(19) United States
(12) Patent Application Publication
(10) Pub. No.: US 2013/0256837 A1
(43) Pub. Date: Oct. 3, 2013

(54) CAPACITOR AND METHOD FOR FORMING THE SAME

(71) Applicant: DONGBU HITEK CO., LTD., Gyeonggi-do (KR)

(72) Inventor: Dong Won SHIN, Chungcheongbuk-do (KR)

(73) Assignee: Dongbu HiTek Co., Ltd., Gyeonggi-do (KR)

(21) Appl. No.: 13/735,466

(22) Filed: Jan. 7, 2013

(30) Foreign Application Priority Data
Mar. 28, 2012 (KR) 10-2012-0031518

(51) Int. Cl. H01L 49/02

(52) U.S. Cl. CPC H01L 28/40
USPC 257/532; 438/381

(57) ABSTRACT

A capacitor and a method of forming a capacitor including forming a first conductive layer, a dielectric film, a second conductive layer, and a hard mask on and/or over a substrate, forming a hard mask pattern and an upper electrode each having a sloped sidewall by etching the hard mask and the first conductive layer, forming a spacer on and/or over the sidewall of each of the hard mask pattern and the upper electrode, and forming a lower electrode by etching the dielectric film and the second conductive layer.

### CROSS REFERENCE TO RELATED APPLICATION

This application claims the benefit of the Patent Korean Application No. 10-2012-0031518, filed on Mar. 28, 2012, which is hereby incorporated by reference in its entirety.

### BACKGROUND

A Metal-Insulator-Metal (MIM) capacitor can be embodied to have a low series resistance and a high Q (Quality Factor). Owing to this, the MIM capacitor is a device that may typically be used in analog and RF circuits.

The MIM capacitor may also be used in a CMOS image sensor wherein, in order to facilitate noise removal, an MIM capacitor with high capacitance may be used. The MIM capacitor with high capacitance may be embodied by increasing a size of the MIM capacitor, or by using a dielectric (insulator) with a high dielectric constant.

However, as the size of the MIM capacitor is increased, a chip size of the CMOS image sensor is liable to also increase. Due to the difficulties of etching the dielectric with a high dielectric constant, patterning of a lower electrode of the MIM capacitor is also difficult, and the generation of by-products due to the etching is liable to cause a short circuit.

In order to solve such a problem, a method may be applied, in which an oxide spacer is formed on an upper electrode and around the dielectric of the MIM capacitor before patterning the lower electrode. However, such a method reduces a distance between the MIM capacitors due to the oxide spacers thus causing the formation of a bridge between the lower electrodes of adjacent MIM capacitors at the time of patterning the lower electrodes, which is liable to result in an inoperative semiconductor device. In order to prevent the bridge from forming, it has been inevitable to increase the chip size.

### SUMMARY

Accordingly, embodiments relate to a capacitor and a method for forming the same.

Embodiments also relate to a Metal-Insulator-Metal (MIM) capacitor and a method of forming the same.

In accordance with embodiments, a capacitor and a method for forming the same are provided, which can prevent a bridge from forming between lower electrodes of adjacent capacitors.

Additional advantages, objectives, and features of embodiments will be set forth in part in the description which follows and in part will become apparent to those having ordinary skill in the art upon examination of the following or may be learned from practice of the embodiments. The objectives, features and other advantages of the invention may be realized and attained by the structure particularly pointed out in the written description and claims hereof as well as the appended drawings.

In accordance with embodiments, a method for forming a capacitor includes forming a first conductive layer, a dielectric film, a second conductive layer, and a hard mask on and/or over a substrate, forming a hard mask pattern and an upper electrode each having a sloped sidewall by etching the hard mask and the first conductive layer, forming a spacer on and/or over the sidewall of each of the hard mask pattern and the upper electrode, and forming a lower electrode by etching the dielectric film and the second conductive layer.

The sidewall of each of the hard mask pattern, and the upper electrode may have an angle of 45°˜85°.

The forming of the lower electrode by etching the dielectric film and the second conductive layer may include removing the dielectric film by using the hard mask pattern and the spacer as an etch mask to expose the second conductive layer, and forming the lower electrode by selectively removing the exposed second conductive layer.

The forming of the hard mask pattern and the upper electrode each having a sloped sidewall by etching the hard mask and the first conductive layer may include using CF₄ gas added with C₄F₈ gas or C₅F₈ gas as etch gas in the formation of the hard mask pattern and the upper electrode each having the sloped sidewall.

The forming of the spacer may include forming an insulating film on and/or over the hard mask pattern, the upper electrode and the dielectric film, and removing the insulating film on and/or over an upper side of the hard mask pattern and the dielectric film, respectively.

The forming of the lower electrode by etching the dielectric film and the second conductive layer may include removing the dielectric film by using the hard mask pattern and the spacer as an etch mask to expose the second conductive layer, forming an anti-reflection coating layer on and/or over the hard mask pattern, the spacer, and the exposed second conductive layer, forming a photoresist pattern on and/or over the anti-reflection coating layer, forming the lower electrode by selectively removing the anti-reflection coating layer and the second conductive layer using the photoresist pattern as a mask, and removing a remaining anti-reflection coating layer.

In accordance with another embodiment, there is provided a capacitor including a substrate, a lower electrode formed on and/or over the substrate, a dielectric film formed on and/or over the lower electrode, an upper electrode formed on and/or over the dielectric film, a hard mask pattern formed on and/or over the upper electrode, and a spacer formed on and/or over a sidewall of each of the hard mask pattern, the upper electrode and the dielectric film, wherein the sidewall of the upper electrode has a first sloped side sloped with respect to an upper side of the lower electrode.

The sidewall of the hard mask pattern may have a second sloped side sloped with respect to the upper side of the lower electrode.

The first sloped side and the second sloped side may have the same angle as each other. The first sloped side and the second sloped side may be positioned on the same plane. The first sloped side and the second sloped side may have angles of 45°˜85°, respectively.

The spacers respectively positioned on and/or over the sidewall of the hard mask pattern and the sidewall of the upper electrode may have the same thicknesses as each other.

The spacer may have a thickness of 0.01 μm˜0.1 μm, and the dielectric film may have a thickness of 0.003 μm˜0.015 μm. The dielectric film may have a dielectric constant higher than or equal to 12.

Each of the first sloped side and the second sloped side may have an angle smaller than an angle of the sidewall of the lower electrode. The spacer may have an underside in contact with an upper side of the dielectric film.

### DRAWINGS

Example FIG. 1 illustrates a sectional view of MIM capacitors in accordance with embodiments.

FIGS. 2 to 9 are sectional views illustrating a process of forming capacitors in accordance with embodiments.

### DESCRIPTION

Reference will now be made in detail to embodiments of the invention, examples of which are illustrated in the accompanying drawings.

A thickness or a size of a layer illustrated in any of the drawings can be exaggerated, omitted or shown schematically for convenience or clarity of description. The sizes of elements may not be shown to scale. Wherever possible, the same reference numbers will be used throughout the drawings to refer to the same or like parts. An MIM capacitor and a method for forming the same in accordance with embodiments will be described with reference to the attached drawings.

As illustrated in example FIG. 1, a section of MIM capacitors 91 and 92 are provided, and the MIM capacitors 91 and 92 each may include a lower electrode 20A formed on and/or over a substrate 10, a dielectric film 30A formed on and/or over the lower electrode 20A, an upper electrode 40A formed on and/or over the dielectric film 30A, a hard mask pattern 50A formed on and/or over the upper electrode 40A, and a spacer 60A formed on and/or over sidewalls of the upper electrode 40A and the hard mask pattern 50A.

The substrate 10 may be a semiconductor substrate, for an example, a silicon substrate, and may include underside wirings.

The lower electrode 20A may be disposed on the substrate 10, and include a conductive layer having a reflection preventive characteristic. For an example, the lower electrode 20A may be formed of at least one selected from a group of materials including Ru, SrRuO₃, Pt, TaN, WN, TiN, TiAlN, Co, Cu, and Hf or an alloy thereof

The dielectric film 30A may be disposed on and/or over the lower electrode 20A. In order to increase a capacitance value of the capacitor 91 or 92, the dielectric film 30A may have a dielectric constant greater than or equal to 12.

The dielectric film 30A may be formed of at least one selected from a group of materials including, for an example, SiN, SiO₂, Al₂O₃, HfO, TaO₅, SrTiO3, CaTiO₃, LaAlO₃, BaZrO₃, and BaZrTiO₃. The dielectric film 30A may have a thickness of 0.003 μm˜0.015 μm.

The upper electrode 40A may be disposed on and/or over the dielectric film 30A. The upper electrode 40A may be formed of a material that is the same as or similar to the lower electrode 20A.

The hard mask pattern 50A may be disposed on and/or over the upper electrode 40A. That is, the hard mask pattern 50A may cover an upper side of the upper electrode 40A. The hard mask pattern 50A may be formed of an oxide film, such as USG (Undoped Silicate Glass), or TEOS (Tetra EthyleOrtho Silicate), or a nitride film, such as SiN or SiON. The hard mask pattern 50A may have a thickness of 0.01 μm˜0.1 μm.

The upper electrode 40A has a sidewall (first sloped side 101) sloped with respect to the upper side 103 of the lower electrode 20A. The first sloped side 101 may have an angle θ1 (a first slope angle) of 45°˜85°. For example, the sidewall of the upper electrode 40A may be at 45°˜85° relative to the lower side of the upper electrode 40A. The upper electrode 40A may have an upper side with an area smaller than an area of the lower side thereof.

The hard mask pattern 50A has a sidewall (a second sloped side 102) sloped with respect to the upper side 103 of the lower electrode 20A. The second sloped side 102 may have an angle θ2 (a second slope angle) of 45°˜85°. For example, the sidewall of the hard mask pattern 50A may be at 45°˜85° relative to the lower side of the hard mask pattern 50A. The hard mask pattern 50A may have an upper side with an area smaller than an area of a lower side thereof.

The first sloped side 101 and the second sloped side 102 may have the same slope angles (Θ1=θ2). However, embodiments are not limited thereto, and the angles may differ from each other in other embodiments.

*33 The first sloped side 101 and the second sloped side 102 may be positioned on the same plane. However, embodiments are not limited thereto, and the first sloped side 101 and the second sloped side 102 may be positioned on planes different from each other in other embodiments.

A slope angle θ3 (a third slope angle) between a sidewall of the dielectric film 30A and the upper side of the lower electrode 20A may differ from the first slope angle θ1 and the second slope angle θ2. For example, the first slope angle θ1 and the second slope angle θ2 may be smaller than the third slope angle θ3 (i.e., θ1<θ2 and θ2<θ3).

The first slope angle θ1 and the second slope angle θ2 may differ from a slope angle θ4 (a fourth slope angle) of a sidewall of the lower electrode 20A. For example, the first slope angle θ1 and the second slope angle θ2 may be smaller than the fourth slope angle θ4.

The spacer 60A may be disposed on the first sloped side 101 of the upper electrode 40A and the second sloped side 102 of the hard mask pattern 50A. The spacer 60A may have an underside in contact with the upper side of the dielectric film 30A.

The spacer 60A may be formed of a nitride film or an oxide film. For example, the spacer 60A may be formed of a nitride film, such as SiN or SiON, or an oxide film, such as USG (Undoped Silicate Glass), or TEOS (Tetra EthyleOrtho Silicate).

For example, if the hard mask pattern 50A is an oxide film, the spacer 60A many be a nitride film, and vice versa. However, embodiments are not limited thereto, and the hard mask pattern 50A and the spacer 60A may be formed of the same or similar material.

The spacer 60A may have a thickness of 0.01 μm˜0.1 μm. A thickness D1 of a spacer 60A portion disposed on and/or over the first sloped side 101 may have variation of less than 0.01 μm from a thickness D2 of a spacer 60A portion disposed on and/or over the second sloped side 102.

Alternatively, the spacer 60A portion positioned on and/or over the first sloped side 101 may have the same thickness as the spacer 60A portion positioned on and/or over the second sloped side 102.

The sloped sidewalls of the upper electrode 40A and the hard mask pattern 50A permit to secure an adequate gap between adjacent capacitors, thus contributing to the prevention of a formation of a bridge between adjacent capacitors, and from the capacitors and a device adjacent thereto.

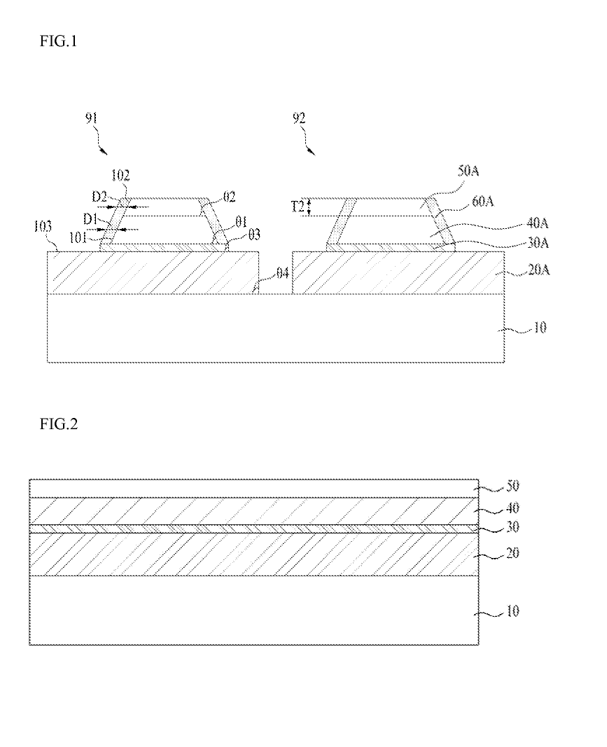

Example FIGS. 2 to 9 are sectional views illustrating a process of forming capacitors in accordance with embodiments.

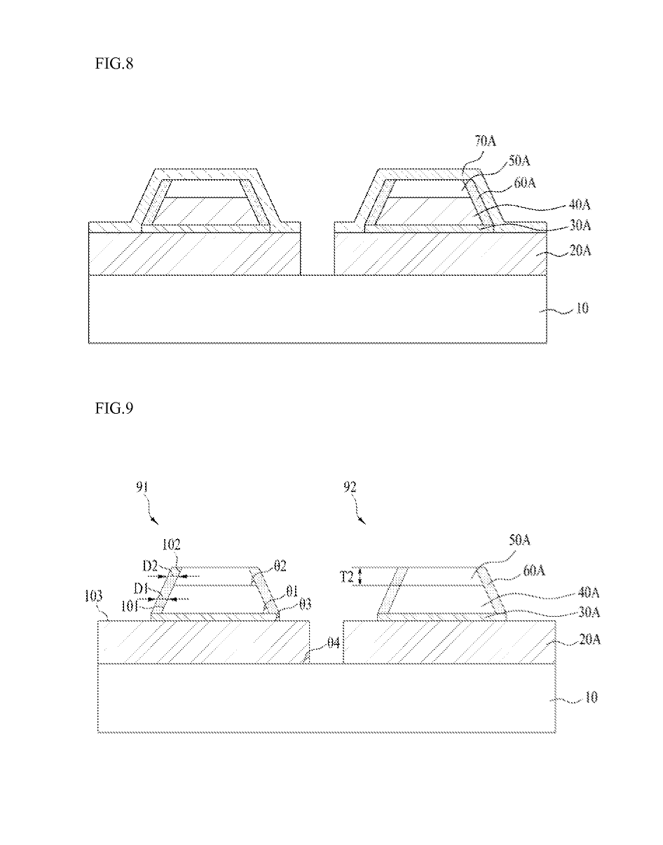

Referring to example FIG. 2, a first conductive layer 20, a dielectric film 30, a second conductive layer 40, and a hard mask 50 may be formed on and/or over a substrate 10 in succession. The first conductive layer 20 may be formed of a material the same as or similar to that of a lower electrode 20A illustrated in example FIG. 8, and the second conductive layer 40 may be formed of a material the same as or similar to that of an upper electrode 40A illustrated in example FIG. 8. The dielectric film 30 may be formed of a material the same as or similar to that of the dielectric film 50A illustrated in example FIG. 8, and the hard mask 50 may be formed of a material the same as or similar to that of a hard mask pattern 50A illustrated in example FIG. 8. The hard mask formed in example FIG. 2 may have a thickness of 0.01 μm˜0.5 μm.

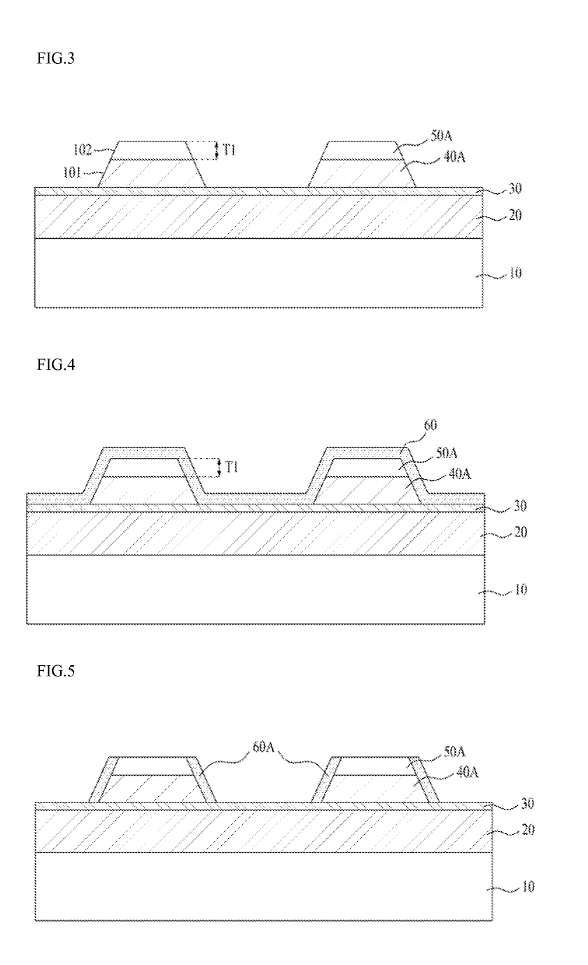

Referring to example FIG. 3, the hard mask 50 and the first conductive layer 20 are subjected to etching to form a hard mask pattern 50A and an upper electrode 40A each having a sloped side wall.

For example, a photoresist pattern may be formed on and/ or over the hard mask 50 by photolithography for patterning the upper electrode 40A. The hard mask 50 may be etched by using the photoresist pattern as an etch mask to expose the first conductive layer 20 to form a hard mask pattern 50A. In embodiments, the hard mask pattern 50A may have a sloped sidewall 102, and the sidewall of the hard mask pattern 50A may be at 45°˜85° from an underside of the hard mask pattern 50A.

In order to form the hard mask pattern 50A having the sloped sidewall 102, CF₄ gas may be used as a main gas and C₄F₈ gas or C₅F₈ gas may be used as doping gas. Bias power in the etching may be 100 W˜300 W.

Then, the first conductive layer 40 may be etched by using the hard mask pattern 50A as an etch mask until the dielectric film 30 is exposed, to form an upper electrode 40A. Since the hard mask pattern 50A has the sloped sidewall 102, the upper electrode 40A can also have a sidewall 101 having the same or similar profile. The sidewall 101 of the upper electrode 40A may be at 45°˜85° from an underside of the upper electrode 40A. A thickness T1 of the hard mask pattern 50A remaining on the upper electrode 40A may be 0.01 μm˜0.1 μm. At the time of etching the first conductive layer 40 to form the upper electrode 40A, the dielectric film 30 may serve as an etch stop film. The dielectric film 30 may have a thickness of 0.003 μm˜0.015 μm for the dielectric film 30 to serve as the etch stop film.

The angle of each of the sidewalls of the hard mask pattern 50A and the upper electrode 40A may be made to be larger than 45° for facilitating the formation of the spacer 60A illustrated in example FIGS. 4 and 5. That is, if the angle of each of the sidewalls is less than 45°, it may be difficult to form the spacer 60A. The angle of each of the sidewalls of the hard mask pattern 50A and the upper electrode 40A is made to be less than than 85° for securing a least amount of space required for suppressing formation of the bridge between adjacent capacitors (see example FIG. 7).

Referring to example FIG. 4, an insulating film 60 is formed on and/or over exposed surfaces of the hard mask pattern 50A, the upper electrode 40A, and the dielectric film 30A. The insulating film 60 may be formed on and/or over exposed surfaces of an upper side and the sidewall of the hard mask pattern 50A, the sidewall of the upper electrode 40A, and the dielectric film 30A. The insulating film 60 may be formed of a material the same as or similar to that of the spacer 60A illustrated in example FIG. 8, and may have a thickness of 0.05 μm˜0.3 μm.

Referring to example FIG. 5, the insulating film 60 is etched to remove portions from upper sides of the hard mask pattern 50A and the dielectric film 30A, to form spacers 60A on and/or over the sidewall of the hard mask pattern 50A and the sidewall of the upper electrode 40A. In this instance, the etching may be blanket etching, and an etch rate of the insulating film 60 may be controlled by controlling a bias power, thereby enabling to control a CD (Critical Dimension) of the spacer 60A.

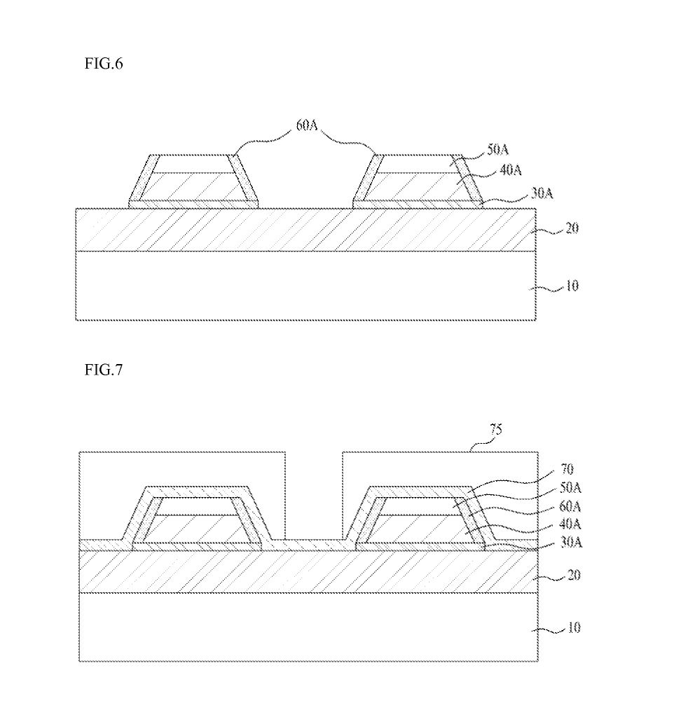

Referring to example FIG. 6, the dielectric film 30A is etched by using the hard mask pattern 50A and the spacer 60A as an etch mask, to expose the second conductive layer 20. By making the etch rate of the dielectric film 30A lower than the etch rate in example FIG. 4, a quantity of polymer can be reduced and damage to the second conductive layer 20 caused by the etching can be reduced.

Referring to example FIG. 7, an anti-reflection coating layer 70, for example, a BARC (bottom of anti-reflection coating) layer, is formed on and/or over the exposed surfaces of the hard mask pattern 50A, the spacer 60A, and the second conductive layer 20A.

Then, a photoresist pattern 75 is formed on and/or over the anti-reflection coating layer 70 by photolithography for forming a lower electrode 20A (see example FIG. 7).

Referring to example FIG. 8, the anti-reflection coating layer 70 and the second conductive layer 20 are selectively etched by using the photoresist pattern 75 as a mask to form the lower electrode 20A.

Referring to example FIG. 9, a remained anti-reflection coating layer 70A is removed. In this instance, a thickness T2 of the hard mask pattern 50A and a thickness of the spacer 60A may be 0.01 μm˜0.1 μm.

If a space between the capacitors is small, or if the capacitor has the sidewall angle of each of the hard mask pattern 50A and the upper electrode greater than 90°, in general, it is liable that a portion of the anti-reflection coating layer formed in a space between the capacitors has a thickness formed thicker than a thickness of the portion of the anti-reflection coating layer formed on the hard mask pattern. The anti-reflection coating layer with a non-uniform thickness may cause imperfect lower electrode patterning, thus causing formation of the bridge between adjacent capacitors.

However, since the capacitor of embodiments has a sloped structure with the sidewall angles of the hard mask pattern 50A and the upper electrode 40A of 45°˜85° respectively, the space between the adjacent capacitors 91 and 92 can be increased.

Since the capacitor of embodiments has a sloped structure with the sidewall angles of the hard mask pattern 50A and the upper electrode 40A of 45°˜85° respectively, the spacer 60A may be formed on and/or over the sidewalls of the hard mask pattern 50A and the upper electrode 40A to have a uniform thickness or a minute variation of thickness. The uniform or minute variation of the thickness of the spacer 60A increases the space between the capacitors.

The large space between the capacitors allows the thickness of the anti-reflection coating layer 75 formed on the exposed surfaces of the hard mask pattern 50A, the spacer 60A, and the second conductive layer 20 to be uniform as illustrated in example FIG. 7. That is, the anti-reflection coating layer 75 can be formed in the space between the capacitors and on the hard mask pattern 50A to have a uniform thickness. Embodiments can thus prevent the bridge from forming between the lower electrodes of the capacitors due to non-uniform formation of the thickness of the anti-reflection coating layer 75.

As has been described, embodiments can prevent the bridge from forming between the lower electrodes of adjacent capacitors.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of forming a capacitor, the method comprising:
forming a first conductive layer, a dielectric film, a second conductive layer, and a hard mask over a substrate;
forming a hard mask pattern and an upper electrode each having a sloped sidewall by etching the hard mask and the second conductive layer;
forming a spacer over the sidewall of each of the hard mask pattern and the upper electrode; and
forming a lower electrode by etching the dielectric film and the first conductive layer.

2. The method of claim 1, wherein the sloped sidewall of each of the hard mask pattern, and the upper electrode is sloped at an angle of 45°˜85°.

3. The method of claim 1, wherein forming the lower electrode by etching the dielectric film and the first conductive layer comprises:
removing the dielectric film by using the hard mask pattern and the spacer as an etch mask to expose the first conductive layer, and forming the lower electrode by selectively removing the exposed first conductive layer.

4. The method of claim 1, wherein the forming the hard mask pattern and the upper electrode each having a sloped sidewall by etching the hard mask and the second conductive layer comprises:
using CF₄ gas added with C₄F₈ gas or C₅F₈ gas as etch gas in the formation of the hard mask pattern and the upper electrode each having the sloped sidewall.

5. The method of claim 1, wherein the forming the spacer comprises:
forming an insulating film over the hard mask pattern, the upper electrode and the dielectric film, and
removing the insulating film from over an upper side of the hard mask pattern and from over a portion of the dielectric film.

6. The method of claim 1, wherein the forming the lower electrode by etching the dielectric film and the first conductive layer comprises:
removing the dielectric film by using the hard mask pattern and the spacer as an etch mask to expose the first conductive layer,
forming an anti-reflection coating layer over the hard mask pattern, the spacer, and the exposed first conductive layer,
forming a photoresist pattern over the anti-reflection coating layer,
forming the lower electrode by selectively removing the anti-reflection coating layer and the first conductive layer by using the photoresist pattern as a mask, and
removing a remaining anti-reflection coating layer.

7. A capacitor comprising:
a substrate;
a lower electrode formed over the substrate;
a dielectric film formed over the lower electrode;
an upper electrode formed over the dielectric film;
a hard mask pattern formed over the upper electrode; and
a spacer formed over a sidewall of each of the hard mask pattern, the upper electrode and the dielectric film,
wherein the sidewall of the upper electrode comprises a first sloped side that is sloped relative to an upper side of the lower electrode.

8. The capacitor of claim 7, wherein the sidewall of the hard mask pattern comprises a second sloped side sloped relative to the upper side of the lower electrode.

9. The capacitor of claim 8, wherein the first sloped side and the second sloped side have a same slope angle.

10. The capacitor of claim 9, wherein the first sloped side and the second sloped side are positioned on a same plane.

11. The capacitor of claim 8, wherein the first sloped side and the second sloped side are respectively sloped at angles between 45°˜85°.

12. The capacitor of claim 7, wherein portions of the spacer respectively positioned on the sidewall of the hard mask pattern and on the sidewall of the upper electrode have a same thicknesses.

13. The capacitor of claim 7, wherein the spacer has a thickness of 0.01 μm˜0.1 μm, and the dielectric film has a thickness of 0.003 μm˜0.015 μm.

14. The capacitor of claim 7, wherein the dielectric film has a dielectric constant greater than or equal to 12.

15. The capacitor of claim 8, wherein each of the first sloped side and the second sloped side has an angle less than an angle of a sidewall of the lower electrode.

16. The capacitor of claim 7, wherein the spacer comprises an underside that is formed to be in contact with an upper side of the dielectric film.

17. A method of forming a capacitor, the method comprising:
forming a first conductive layer over a substrate;
forming a dielectric film over the first conductive layer;
forming a second conductive layer over the dielectric film;
forming a hard mask over the second conductive layer;
forming a hard mask pattern and an upper electrode each having a sloped sidewall by etching the hard mask and the second conductive layer;
forming a spacer over the sidewall of each of the hard mask pattern and the upper electrode; and
forming a lower electrode by etching the dielectric film and the first conductive layer.

18. The method of claim 17, wherein forming the lower electrode by etching the dielectric film and the first conductive layer comprises:
removing the dielectric film by using the hard mask pattern and the spacer as an etch mask to expose the first conductive layer, and
forming the lower electrode by selectively removing the exposed first conductive layer.

19. The method of claim 17, wherein the forming the spacer comprises:
forming an insulating film over the hard mask pattern, the upper electrode and the dielectric film, and
removing the insulating film from over an upper side of the hard mask pattern and from over a portion of the dielectric film.

20. The method of claim 17, wherein the forming the lower electrode by etching the dielectric film and the first conductive layer comprises:
removing the dielectric film by using the hard mask pattern and the spacer as an etch mask to expose the first conductive layer,
forming an anti-reflection coating layer over the hard mask pattern, the spacer, and the exposed first conductive layer,
forming a photoresist pattern over the anti-reflection coating layer,
forming the lower electrode by selectively removing the anti-reflection coating layer and the first conductive layer by using the photoresist pattern as a mask, and
removing a remaining anti-reflection coating layer.
